(19) United States
(12) Patent Application Publication
(10) Pub. No.: US 2023/0140984 A1
(43) Pub. Date: May 11, 2023

(54) DISPLAY DEVICE AND METHOD OF MANUFACTURING THE SAME

(71) Applicant: Samsung Display Co., Ltd., Yongin-si (KR)

(72) Inventors: JUNHO SIM, Hwaseong-si (KR); HYE SUN KIM, Goyang-si (KR); SANGHYUN LEE, Hwaseong-si (KR); JAEHUN LEE, Seongnam-si (KR); YANG-HO JUNG, Seoul (KR); PIL SOON HONG, Seoul (KR)

(73) Assignee: Samsung Display Co., Ltd., Yongin-si (KR)

(21) Appl. No.: 17/942,479

(22) Filed: Sep. 12, 2022

(30) Foreign Application Priority Data
Nov. 5, 2021 (KR) 10-2021-0151644

(51) Int. Cl. H01L 27/32; H01L 51/56; H01L 51/52

(52) U.S. Cl. CPC H01L 27/3246; H01L 51/56; H01L 51/5284; H01L 2227/323

(57) ABSTRACT

A display device includes an insulating layer disposed on a base layer, a first lower electrode disposed on the insulating layer, a second lower electrode disposed on the insulating layer and spaced apart from the first lower electrode, a pixel definition layer disposed on the insulating layer and including pixel openings exposing at least a portion of each of the first lower electrode and the second lower electrode, and a sacrificial layer disposed between the pixel definition layer and the insulating layer and including a first side surface defining sacrificial openings corresponding to the pixel openings. The first side surface is overlapped by the pixel definition layer in a plan view.

### CROSS-REFERENCE TO RELATED APPLICATION(S)

This application claims priority to and benefits of Korean Patent Application No. 10-2021-0151644 under 35 U.S.C. § 119, filed on Nov. 5, 2021 in the Korean Intellectual Property Office (KIPO), the entire contents of which are incorporated herein by reference.

### BACKGROUND

### 1. Technical Field

The disclosure relates to a display device with improved light emission reliability and a method of manufacturing the display device.

### 2. Description of the Related Art

A reflection of a natural external light occurs on a surface of a display device. The reflection of the light deteriorates a visibility of the display device. The display device may be affected by an external ultraviolet light. In case that the display device is continuously exposed to the ultraviolet light, a color of images displayed in the display device may be changed.

In recent years, a pixel definition layer of a display panel may include a light blocking material to prevent the reflection of the external light from occurring. In case that a content ratio of the light blocking material increases, an optical density of the pixel definition layer increases, and thus, the reflection of the external light is effectively prevented. However, bad pixels are inevitable in the process of patterning the pixel defining layer.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device with improved flexible characteristics by providing a pixel definition layer having a light blocking property and preventing a reflection of an external light by a lower line without employing a separate anti-reflective film and a method of manufacturing the display device.

The disclosure provides a display device capable of preventing defects, such as a formation of unlit pixels or a reduction of a luminance lifetime, due to a light blocking material included in a pixel definition layer in a process of forming the pixel definition layer with the light blocking property and a method of manufacturing the display device.

Embodiments of the disclosure provide a display device that may include an insulating layer disposed on a base layer, a first lower electrode disposed on the insulating layer, a second lower electrode disposed on the insulating layer and spaced apart from the first lower electrode, a pixel definition layer disposed on the insulating layer and including pixel openings exposing at least a portion of each of the first lower electrode and the second lower electrode, and a sacrificial layer disposed between the pixel definition layer and the insulating layer and including a first side surface defining sacrificial openings corresponding to the pixel openings. The first side surface may be overlapped by the pixel definition layer in a plan view.

The sacrificial layer may include a first sacrificial pattern adjacent to the first lower electrode, and a second sacrificial pattern adjacent to the second lower electrode and spaced apart from the first sacrificial pattern, and the sacrificial openings may include a first sacrificial opening defined in the first sacrificial pattern and exposing the at least the portion of the first lower electrode, and a second sacrificial opening defined in the second sacrificial pattern and exposing the at least the portion of the second lower electrode.

The pixel definition layer may include a first pixel definition pattern overlapping the first sacrificial pattern in a plan view and a second pixel definition pattern overlapping the second sacrificial pattern in a plan view and spaced apart from the first pixel definition pattern.

The first sacrificial pattern may include a second side surface facing the first side surface of the first sacrificial pattern and spaced farther from the first lower electrode than the first side surface of the first sacrificial pattern may be, the second sacrificial pattern includes a third side surface facing the first side surface of the second sacrificial pattern and spaced farther from the second lower electrode than the first side surface of the second sacrificial pattern may be, the second side surface may be overlapped by the first pixel definition pattern in a plan view, the third side surface may be overlapped by the second pixel definition pattern in a plan view, and at least a portion of the second side surface may face a portion of the third side surface.

The display device may further include a cover layer overlapping a separation space between the first pixel definition pattern and the second pixel definition pattern in a plan view and including an organic material.

The cover layer may further include a light blocking material.

The pixel definition layer may include a light blocking material.

The pixel definition layer may have an optical density equal to or greater than about 1.0.

An etch rate of the sacrificial layer may be faster than an etch rate of each of the first and second lower electrodes.

At least a portion of the sacrificial layer may overlap at least a portion of an end area of each of the first and second lower electrodes in a plan view.

Embodiments of the disclosure provide a display device that may include a first light emitting element including a lower electrode, an upper electrode, and a light emitting layer disposed between the lower electrode and the upper electrode, a second light emitting element including a lower electrode, an upper electrode, and a light emitting layer disposed between the lower electrode and the upper electrode, transistors electrically connected to the lower electrode of the first light emitting element and the lower electrode of the second light emitting element, a first pixel definition pattern including a first pixel opening through which at least a portion of the lower electrode of the first light emitting element may be exposed, a second pixel definition pattern including a second pixel opening through which at least a portion of the lower electrode of the second light emitting element may be exposed, a first sacrificial pattern overlapped by the first pixel definition pattern in a plan view, and a second sacrificial pattern overlapped by the second pixel definition pattern in a plan view and spaced apart from the first sacrificial pattern. The transistors may not overlap an area between the first pixel definition pattern and the second pixel definition pattern in a plan view.

Each of the first pixel definition pattern and the second pixel definition pattern may include a light blocking material.

The display device may further include a cover layer overlapping a separation space between the first pixel definition pattern and the second pixel definition pattern in a plan view.

Embodiments of the disclosure provide a method of manufacturing a display device. The manufacturing method of the display device may include forming a preliminary sacrificial layer on an insulating layer on which a first lower electrode and a second lower electrode spaced apart from the first lower electrode may be disposed, forming a light blocking layer including a light blocking material on the preliminary sacrificial layer, patterning the light blocking layer such that areas of the preliminary sacrificial layer may be exposed, the areas of the preliminary sacrificial layer overlapping the first and second lower electrodes in a plan view, etching the preliminary sacrificial layer in the areas exposed through the patterned light blocking layer using the patterned light blocking layer as a mask, and heat-treating the patterned light blocking layer.

A pixel definition layer overlapping a side surface of the preliminary sacrificial layer in a plan view may be formed from the patterned light blocking layer by the heat-treating of the light blocking layer.

The patterning of the light blocking layer may include forming a first preliminary pixel definition pattern to expose an area of the preliminary sacrificial layer overlapping the first lower electrode in a plan view, and forming a second preliminary pixel definition pattern spaced apart from the first preliminary pixel definition pattern to expose an area of the preliminary sacrificial layer overlapping the second lower electrode in a plan view.

The etching of the preliminary sacrificial layer may include forming a first sacrificial pattern using the first preliminary pixel definition pattern as a mask, and forming a second sacrificial pattern using the second preliminary pixel definition pattern as a mask.

The heat-treating of the light blocking layer may include forming a first pixel definition pattern overlapping a side surface of the first sacrificial pattern in a plan view, and forming a second pixel definition pattern overlapping a side surface of the second sacrificial pattern in a plan view.

The method may further include forming a cover layer overlapping a separation space between the first pixel definition pattern and the second pixel definition pattern in a plan view after the heat-treating of the light blocking layer.

The etching of the preliminary sacrificial layer may be performed by a wet etching method.

According to the above, the sacrificial layer may be disposed between the lower electrode and the pixel definition layer, and the area of the sacrificial layer overlapping the lower electrode may be removed in the process of patterning the sacrificial layer. Therefore, residual particles and/or a fine residual layer caused by the light blocking material formed on the sacrificial layer may be removed. Accordingly, defects, such as a formation of unlit pixels and a reduction of luminance lifetime, may not be generated in the display device.

### BRIEF DESCRIPTION OF THE DRAWINGS

The above and other advantages of the disclosure will become readily apparent by reference to the following detailed description when considered in conjunction with the accompanying drawings wherein:

FIG. 1A is a schematic perspective view of a display device in an unfolded state according to an embodiment of the disclosure;

FIG. 1B is a schematic perspective view of a folding operation of a display device according to an embodiment of the disclosure;

FIG. 1C is a schematic plan view of a display device in a folded state according to an embodiment of the disclosure;

FIG. 1D is a schematic perspective view of a folding operation of a display device according to an embodiment of the disclosure;

FIG. 2 is a schematic cross-sectional view of a display device according to an embodiment of the disclosure;

FIG. 3A is a schematic plan view of a display panel according to an embodiment of the disclosure;

FIG. 3B is a schematic representation of a circuit of a pixel according to an embodiment of the disclosure;

FIG. 4 is a schematic plan view of a portion of a display panel according to an embodiment of the disclosure;

FIG. 5 is a schematic cross-sectional view taken along line I-I′ of FIG. 4;

FIG. 6 is a schematic cross-sectional view taken along line I-I′ of FIG. 4;

FIGS. 7A to 7H are schematic cross-sectional views of a method of manufacturing a display panel according to an embodiment of the disclosure; and

FIG. 8 is a schematic cross-sectional view of a method of manufacturing a display panel according to an embodiment of the disclosure.

### DETAILED DESCRIPTION OF THE EMBODIMENTS

In the disclosure, it will be understood that when an element (or area, layer, or portion) is referred to as being “on”, “connected to” or “coupled to” another element or layer, it can be directly on, connected or coupled to another element or layer or intervening elements or layers may be present. Further, “connection” or “coupling” may refer to a physical or electrical connection or coupling.

Like numerals refer to like elements throughout. In the drawings, the thickness, ratio, and dimension of components may be exaggerated for effective description of the technical content. As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc., may be used herein to describe various elements, these elements are not to be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another element(s) or feature(s) as illustrated in the figures.

It will be further understood that the terms “comprises”, “has”, have“, “includes” and the like, when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as “not overlapping” or to “not overlap” another element, this may include that the elements are spaced apart from each other, offset from each other, or set aside from each other or any other suitable term as would be appreciated and understood by those of ordinary skill in the art.

“About”, “approximately”, and “substantially”, as used herein, are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

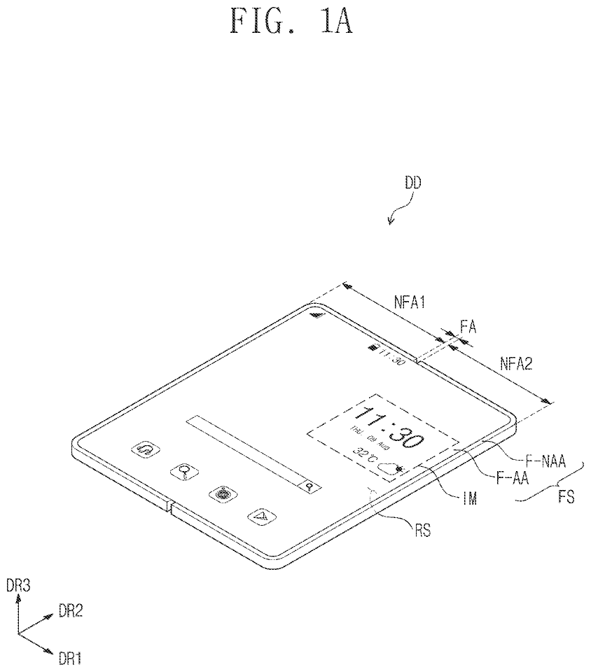

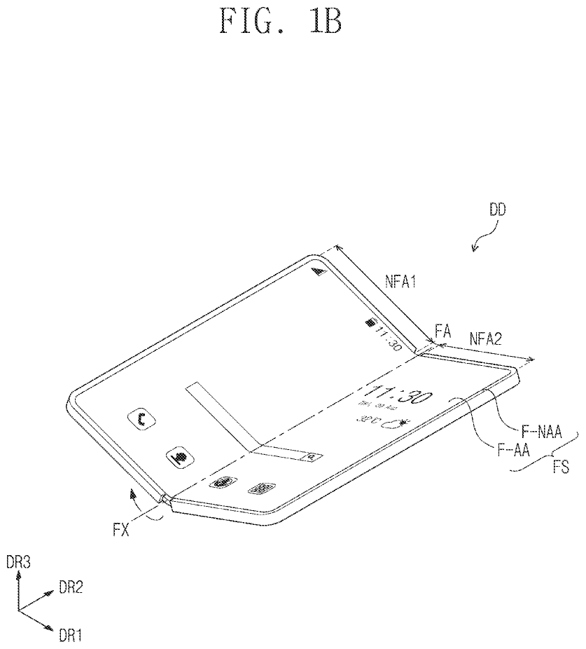

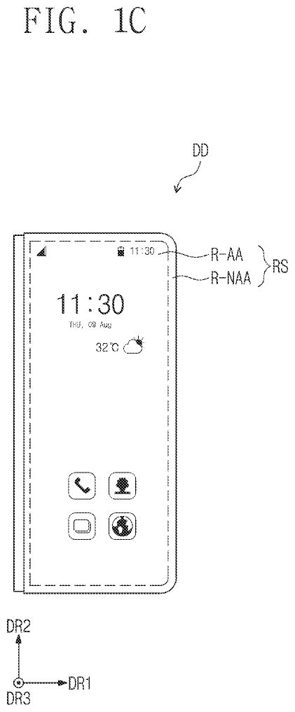

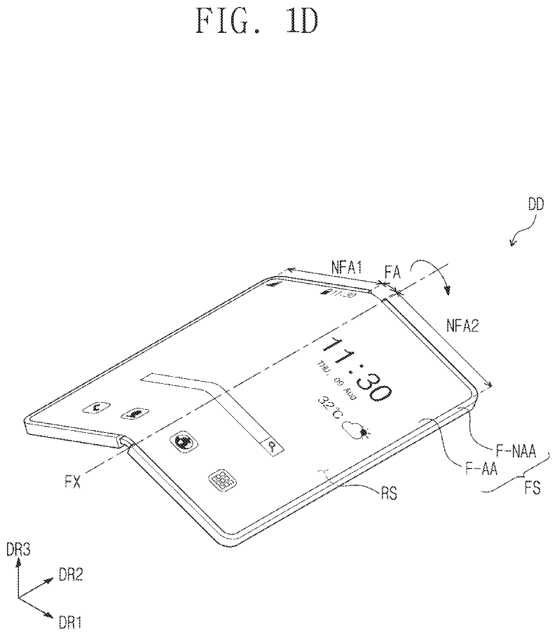

FIG. 1A is a schematic perspective view of a display device DD in an unfolded state according to an embodiment of the disclosure. FIG. 1B is a schematic perspective view of a folding operation of the display device DD according to an embodiment of the disclosure. FIG. 1C is a schematic plan view of the display device DD in a folded state according to an embodiment of the disclosure. FIG. 1D is a schematic perspective view of a folding operation of the display device DD according to an embodiment of the disclosure.

Referring to FIG. 1A, the display device DD may be a device activated in response to electrical signals. A smartphone is shown as the display device DD. However, the display device DD may include various embodiments. For example, the display device DD may include a tablet computer, a notebook computer, a computer, or a smart television.

The display device DD may display an image IM through a first display surface FS that may be substantially parallel to each of a first direction DR1 and a second direction DR2 toward a third direction DR3. The first display surface FS through which the image IM may be displayed may correspond to a front surface of the display device DD. The image IM may include a video and a still image. FIG. 1A shows an internet search box and a clock widget as an example of the image IM.

In an embodiment, front (or upper) and rear (or lower) surfaces of each member of the display device DD may be defined with respect to a direction in which the image IM may be displayed. The front and rear surfaces may be opposite to each other in the third direction DR3, and a normal line direction of each of the front and rear surfaces may be substantially parallel to the third direction DR3.

A separation distance between the front surface and the rear surface in the third direction DR3 may correspond to a thickness or a height of the display device DD in the third direction DR3. Directions indicated by the first, second, and third directions DR1, DR2, and DR3 may be relative to each other and may be changed to other directions.

The display device DD may sense an external input applied thereto from an outside. The external input may include various forms of inputs provided from the outside of the display device DD. For example, the external inputs may include the external input (e.g., a hovering input) applied in case of approaching close to or adjacent to the display device DD at a distance as well as a touch input by a user's body part (e.g., a user's hand). The external inputs may be provided in the form of force, pressure, temperature, light, electromagnetic pen, etc.

According to an embodiment, the display device DD may include the first display surface FS. The first display surface FS may include a first active area F-AA and a first peripheral area F-NAA.

The first active area F-AA may be activated in response to the electrical signals. The image IM may be displayed through the first active area F-AA, and various external inputs may be sensed through the first active area F-AA.

The first peripheral area F-NAA may be defined adjacent to the first active area F-AA. The first peripheral area F-NAA may have a color. The first peripheral area F-NAA may surround the first active area F-AA. Accordingly, the first active area F-AA may have a shape substantially defined by the first peripheral area F-NAA, however, this is merely an example. According to an embodiment, the first peripheral area F-NAA may be defined adjacent to a side of the first active area F-AA or may be omitted.

According to an embodiment, the display device DD may include at least one folding area FA and non-folding areas NFA1 and NFA2 extending from the folding area FA. The non-folding areas NFA1 and NFA2 may include a first non-folding area NFA1 and a second non-folding area NFA2 that may be arranged in the first direction DR1 with the folding area FA interposed therebetween.

Referring to FIG. 1B, the display device DD may be folded with respect to a folding axis FX that is imaginary and extends in the second direction DR2. The display device DD may be folded about the folding axis FX to be in an in-folding state where the first non-folding area NFA1 of the first display surface FS faces the second non-folding area NFA2 of the first display surface FS.

Referring to FIG. 1C, a second display surface RS of the display device DD may be viewed by a user during the in-folding state of the display device DD. As shown in FIG. 1A, the second display surface RS may be opposite to the first display surface FS (refer to FIG. 1A) and may correspond to a rear surface of the display device DD.

The second display surface RS may include a second active area R-AA through which the image may be displayed. The second active area R-AA may be activated in response to the electrical signals. The second active area R-AA may be an area through which the image may be displayed and various external inputs may be sensed.

A second peripheral area R-NAA may be defined adjacent to the second active area R-AA. The second peripheral area R-NAA may have a color. The second peripheral area R-NAA may surround the second active area R-AA.

Although not shown in figures, the second display surface RS may further include an electronic module area in which an electronic module including various components may be disposed, and the second display surface RS is not particularly limited.

Referring to FIG. 1D, the display device DD may be folded with respect to the folding axis FX to be in an out-folding state where the first non-folding area NFA1 of the second display surface RS faces the second non-folding area NFA2 of the second display surface RS.

However, the display device DD is not limited thereto or thereby. The display device DD may be folded with respect to folding axes such that a portion of the first display surface FS faces a portion of the second display surface RS, and the number of the folding axes and the number of non-folding areas are not particularly limited.

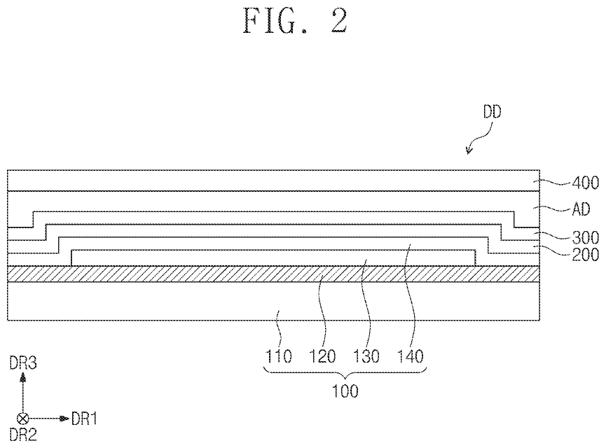

FIG. 2 is a schematic cross-sectional view of the display device DD according to an embodiment of the disclosure.

Referring to FIG. 2, the display device DD may include a display panel 100, an input sensor 200, an optical control layer 300, and a window 400.

The display panel 100 may be a light emitting type display panel. For example, the display panel 100 may be an organic light emitting display panel, an inorganic light emitting display panel, a micro-LED display panel, or a nano-LED display panel. The display panel 100 may include a base layer 110, a circuit element layer 120, a light emitting element layer 130, and an encapsulation layer 140.

The base layer 110 may provide a base surface on which the circuit element layer 120 may be disposed. The base layer 110 may be a rigid substrate or a flexible substrate that may be bendable, foldable, and/or rollable. The base layer 110 may be a glass substrate, a metal substrate, and/or a polymer substrate, however, embodiments are not limited thereto or thereby. According to an embodiment, the base layer 110 may be an inorganic layer, an organic layer, or a composite material layer.

The base layer 110 may have a multi-layer structure. For instance, the base layer 110 may include a first synthetic resin layer, an inorganic layer having a single-layer or multi-layer structure, and a second synthetic resin layer disposed on the inorganic layer having the single-layer or multi-layer structure. Each of the first and second synthetic resin layers may include a polyimide-based resin, however, embodiments are not particularly limited.

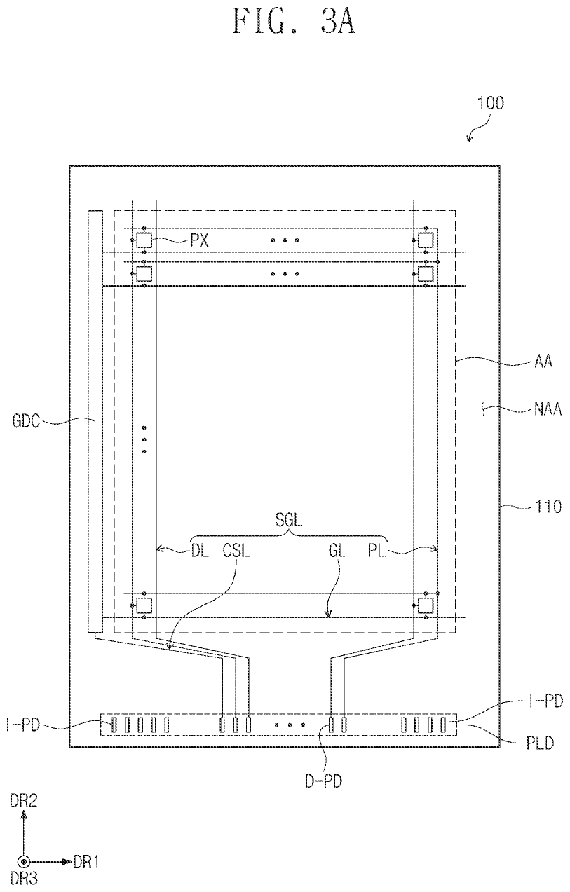

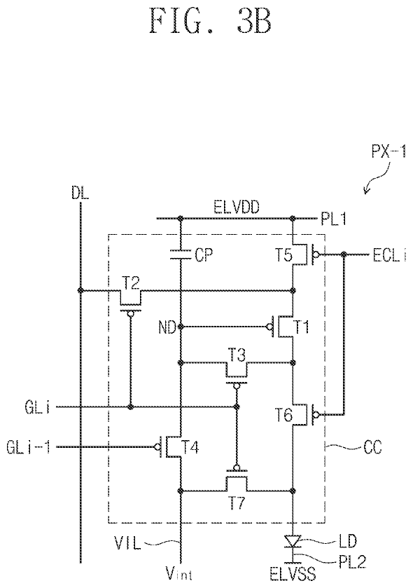

The circuit element layer 120 may be disposed on the base layer 110. The circuit element layer 120 may include an insulating layer, a semiconductor pattern, a conductive pattern, and a signal line. The circuit element layer 120 may include a driving circuit of pixels PX described with reference to FIG. 3A.

The light emitting element layer 130 may be disposed on the circuit element layer 120. The light emitting element layer 130 may include a light emitting element of the pixels PX described with reference to FIG. 3A. For example, the light emitting element may include at least one of an organic light emitting material, an inorganic light emitting material, an organic-inorganic light emitting material, a quantum dot, a quantum rod, a micro-LED, and a nano-LED.

The encapsulation layer 140 may be disposed on the light emitting element layer 130. The encapsulation layer 140 may protect the light emitting element layer 130 from moisture, oxygen, and a foreign substance such as dust particles. The encapsulation layer 140 may include at least one inorganic layer. According to an embodiment, the encapsulation layer 140 may include a stack structure of an inorganic layer/an organic layer/an inorganic layer.

The input sensor 200 may be disposed on the display panel 100. The input sensor 200 may sense an external input applied thereto from the outside. The external input may be a user's input. The user's input may include a variety of external inputs, such as a part of user's body, light, heat, pen, or pressure.

The input sensor 200 may be formed on the display panel 100 through successive processes. The input sensor 200 may be disposed directly on the display panel 100. In the disclosure, the expression “a component A is disposed directly on a component B” may mean that no intervening elements may be present between the component A and the component B. For example, an adhesive layer may not be disposed between the input sensor 200 and the display panel 100.

The optical control layer 300 may be disposed on the input sensor 200. The optical control layer 300 may be disposed directly on the input sensor 200 through successive processes.

The optical control layer 300 may include a color filter overlapping a light emitting area described later. The color filter may include a first color filter, a second color filter, and a third color filter. The first color filter may transmit a first color light provided from the light emitting element layer 130 of the display panel 100, the second color filter may transmit a second color light provided from the light emitting element layer 130, and the third color filter may transmit a third color light provided from the light emitting element layer 130.

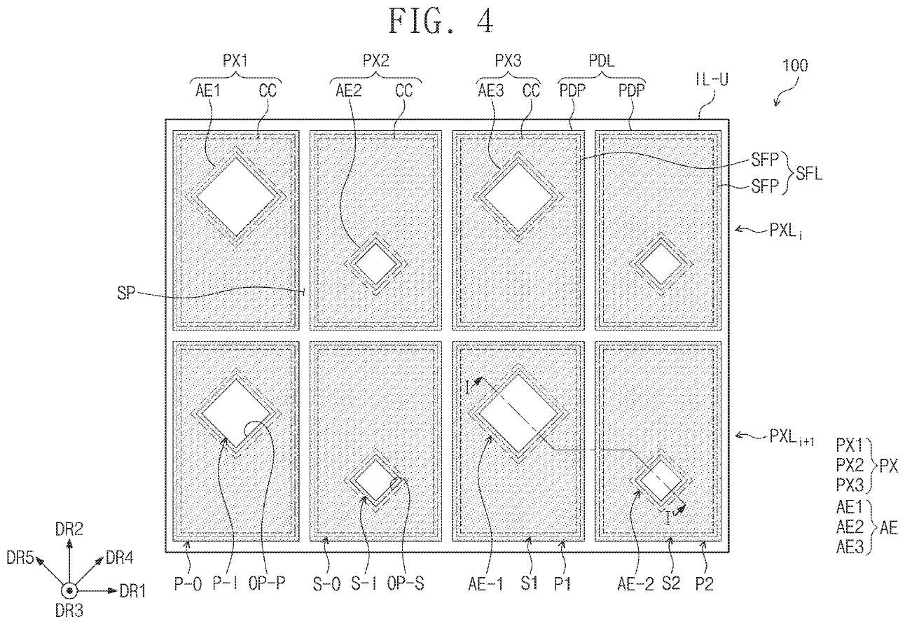

The optical control layer 300 may further include a light blocking pattern overlapping a reflective structure disposed under the optical control layer 300. In a case where a pixel definition layer PDL (refer to FIG. 4) described later includes a light blocking material and an optical density of the pixel definition layer PDL may be high, the light blocking pattern may be omitted.

According to an embodiment, the optical control layer 300 may be omitted.

The window 400 may be disposed on the optical control layer 300. The window 400 may be coupled to the optical control layer 300 by an adhesive layer AD. The adhesive layer AD may be a pressure sensitive adhesive (PSA) film or an optically clear adhesive (OCA).

The window 400 may include at least one base layer. The base layer may be a glass substrate or a synthetic resin film. The window 400 may have a multi-layer structure. The window 400 may include a thin film glass substrate and a synthetic resin film disposed on the thin film glass substrate. The thin film glass substrate may be coupled to the synthetic resin film by an adhesive layer, and the adhesive layer and the synthetic resin film may be separated from the thin film glass substrate to be replaced.

According to an embodiment, the adhesive layer AD may be omitted, and the window 400 may be disposed directly on the optical control layer 300. An organic material, an inorganic material, and/or a ceramic material may be coated on the optical control layer 300.

FIG. 3A is a schematic plan view of the display panel 100 according to an embodiment of the disclosure, and FIG. 3B is a schematic representation of a circuit of a pixel PX-1 according to an embodiment of the disclosure.

Referring to FIG. 3A, the display panel 100 may include the base layer 110 including the first active area F-AA and the first peripheral area F-NAA or the second active area R-AA and the second peripheral area R-NAA, which are described with reference to FIGS. 1A to 1D. Hereinafter, for the convenience of explanation, the first and second active areas F-AA and R-AA may be referred to as an active area AA, and the first and second peripheral areas F-NAA and R-NAA may be referred to as a peripheral area NAA.

The display panel 100 may include the pixels PX disposed in the active area AA and signal lines SGL electrically connected to the pixels PX. The display panel 100 may include a driving circuit GDC and a pad part PLD, which may be disposed in the peripheral area NAA.

The pixels PX may be arranged in the first direction DR1 and the second direction DR2. The pixels PX may include pixel rows extending in the first direction DR1 and arranged in the second direction DR2 and pixel columns extending in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and may provide control signals to the driving circuit GDC.

The driving circuit GDC may include a gate driving circuit. The gate driving circuit may generate gate signals and may sequentially output the generated gate signals to the gate lines GL. The gate driving circuit may further output another control signal to the pixel driving circuit.

Although not shown separately, the pad part PLD may be connected to a circuit substrate. The pad part PLD may include pixel pads D-PD and input pads I-PD.

The pixel pads D-PD may be pads that connect the circuit substrate (not shown) to the display panel DP. Each of the pixel pads D-PD may be connected to a corresponding signal line among the signal lines SGL. The pixel pads D-PD may be connected to corresponding pixels PX via the signal lines SGL. A pixel pad among the pixel pads D-PD may be connected to the driving circuit GDC.

The input pads I-PD may be pads that connect the circuit substrate (not shown) to the input sensor 200. In FIG. 3A, the input pads I-PD may be disposed in the display panel 100, however, embodiments are not limited thereto or thereby. According to an embodiment, the input pads I-PD may be disposed in the input sensor 200 and may be connected to the pixel pads D-PD and a separate circuit substrate.

Referring to FIG. 3B, the pixel PX-1 among the pixels PX shown in FIG. 3A may be electrically connected to signal lines. FIG. 3B shows gate lines GLi and GLi-1, a data line DL, a first power line PL1, a second power line PL2, an initialization power line VIL, and a light emission control line ECLi among the signal lines, however, they are merely an example. The pixel PX-1 according to an embodiment of the disclosure may be further connected to various signal lines, and some of the signal lines shown in FIG. 3A may be omitted.

The pixel PX-1 may include a pixel circuit CC and a light emitting element LD. The pixel circuit CC may include transistors T1 to T7 and a capacitor CP. The pixel circuit CC may control an amount of current flowing through the light emitting element LD in response to a data signal.

The light emitting element LD may emit a light at a luminance in response to the amount of current provided from the pixel circuit CC. To this end, a first power ELVDD may have a level that may be set higher than a level of a second power ELVSS.

Each of the transistors T1 to T7 may include an input electrode (or a source electrode), an output electrode (or a drain electrode), and a control electrode (or a gate electrode). In the following descriptions, for the convenience of explanation, one electrode of the input electrode and the output electrode may be referred to as a first electrode, and another electrode of the input electrode and the output electrode may be referred to as a second electrode.

A first electrode of a first transistor T1 may be connected to the first power line PL1 via a fifth transistor T5. The first power line PL1 may be a line to which the first power ELVDD may be applied. A second electrode of the first transistor T1 may be connected to an anode electrode of the light emitting element LD via a sixth transistor T6. The first transistor T1 may be referred to as a driving transistor in the disclosure. The first transistor T1 may control the amount of current flowing through the light emitting element LD in response to a voltage applied to a control electrode of the first transistor T1.

A second transistor T2 may be connected between the data line DL and the first electrode of the first transistor T1. A control electrode of the second transistor T2 may be connected to an i-th gate line GLi. In case that an i-th gate signal is applied to the i-th gate line GLi, the second transistor T2 may be turned on and may electrically connect the data line DL to the first electrode of the first transistor T1.

A third transistor T3 may be connected between the second electrode of the first transistor T1 and the control electrode of the first transistor T1. A control electrode of the third transistor T3 may be connected to the i-th gate line GLi. In case that the i-th gate signal is applied to the i-th gate line GLi, the third transistor T3 may be turned on and may electrically connect the second electrode of the first transistor T1 to the control electrode of the first transistor T1. Accordingly, in case that the third transistor T3 is turned on, the first transistor T1 may be connected in a diode configuration.

A fourth transistor T4 may be connected between a node ND and the initialization power line VIL. A control electrode of the fourth transistor T4 may be connected to an (i−1)th gate line GLi-1. The node ND may be a node at which the fourth transistor T4 may be connected to the control electrode of the first transistor T1. In case that an (i−1)th gate signal is applied to the (i−1)th gate line GLi-1, the fourth transistor T4 may be turned on and may provide an initialization voltage Vint to the node ND.

The fifth transistor T5 may be connected between the first power line PL1 and the first electrode of the first transistor T1. The sixth transistor T6 may be connected between the second electrode of the first transistor T1 and the anode electrode of the light emitting element LD. A control electrode of the fifth transistor T5 and a control electrode of the sixth transistor T6 may be connected to an i-th light emission control line ECLi.

A seventh transistor T7 may be connected between the initialization power line VIL and the anode electrode of the light emitting element LD. A control electrode of the seventh transistor T7 may be connected to the i-th gate line GLi. In case that the i-th gate signal is applied to the i-th gate line GLi, the seventh transistor T7 may be turned on and may provide the initialization voltage Vint to the anode electrode of the light emitting element LD.

The seventh transistor T7 may improve a black expression ability of the pixel PX-1. In detail, in case that the seventh transistor T7 is turned on, a parasitic capacitance (not shown) of the light emitting element LD may be discharged. Accordingly, in case of implementing a black luminance, the light emitting element LD may not emit the light due to a leakage current from the first transistor T1, and thus the black expression ability may be improved.

In FIG. 3B, the control electrode of the seventh transistor T7 may be connected to the i-th gate line GLi, however, embodiments are not limited thereto or thereby. According to an embodiment, the control electrode of the seventh transistor T7 may be connected to the (i−1)th gate line GLi-1 or an (i+1)th gate line (not shown).

FIG. 3B shows a PMOS as a reference of the pixel circuit CC, however, embodiments are not limited thereto or thereby. According to an embodiment, the pixel circuit CC may be implemented by an NMOS. According to an embodiment, the pixel circuit CC may be implemented by a combination of the NMOS and the PMOS.

The capacitor CP may be disposed between the first power line PL1 and the node ND. The capacitor CP may be charged with a voltage corresponding to the data signal. In case that the fifth and sixth transistors T5 and T6 may be turned on due to the voltage charged in the capacitor CP, the amount of the current flowing through the first transistor T1 may be determined.

The light emitting element LD may be electrically connected to the sixth transistor T6 and the second power line PL2. The light emitting element LD may receive the second power ELVSS via the second power line PL2.

The light emitting element LD may emit the light with the voltage corresponding to a difference between the signal provided through the sixth transistor T6 and the second power ELVSS provided through the second power line PL2.

In the disclosure, the structure of the pixel PX-1 is not limited to the structure shown in FIG. 3B. According to an embodiment of the disclosure, the pixel PX-1 may be implemented in various ways to allow the light emitting element LD to emit the light.

FIG. 4 is a schematic plan view of a portion of the display panel 100 according to an embodiment of the disclosure, and FIG. 5 is a schematic cross-sectional view taken along line I-I′ of FIG. 4.

Referring to FIG. 4, the pixels PX may include a first color pixel PX1, a second color pixel PX2, and a third color pixel PX3. The first, second, and third color pixels PX1, PX2, and PX3 may provide lights having different colors from each other. The first color pixel PX1 may provide the first color light, the second color pixel PX2 may provide the second color light, and the third color pixel PX3 may provide the third color light.

FIG. 4 is an enlarged plan view showing two pixel rows PXLᵢ and PXLᵢ₊₁ arranged in the second direction DR2 among the pixel rows described with reference to FIG. 3A.

An i-th pixel row PXLᵢ may include the first color pixel PX1, the second color pixel PX2, the third color pixel PX3, and the second color pixel PX2, which may be arranged in the first direction DR1. An (i+1)th pixel low PXLᵢ₊₁ may include the third color pixel PX3, the second color pixel PX2, the first color pixel PX1, and the second color pixel PX2 arranged in the first direction DR1. Four pixels arranged in each of the pixel rows PXLᵢ and PXLᵢ₊₁ shown in FIG. 4 may be repeatedly arranged in the first direction DR1.

FIG. 4 shows only a lower electrode AE and the pixel circuit CC, which may be components of the light emitting element LD (refer to FIG. 3B), of the pixels PX. As an example, the first color pixel PX1 may include the pixel circuit CC and a first group electrode AE1 connected to the pixel circuit CC, the second color pixel PX2 may include the pixel circuit CC and a second group electrode AE2 connected to the pixel circuit CC, and the third color pixel PX3 may include the pixel circuit CC and a third group electrode AE3 connected to the pixel circuit CC.

In FIG. 4, the lower electrodes AE of the pixels PX are shown by a long dashed line, and the pixel circuit CC is shown by a short dashed line.

Referring to FIG. 4, the lower electrodes AE, the pixel definition layer PDL, and a sacrificial layer SFL may be disposed on an insulating layer IL-U (hereinafter, referred to as an upper insulating layer) disposed at an uppermost position of the circuit element layer 120 (refer to FIG. 2). The pixel circuit CC may be disposed under the upper insulating layer IL-U. Each of the first, second, and third group electrodes AE1, AE2, and AE3 may be connected to a corresponding pixel circuit CC via a contact hole defined through the upper insulating layer IL-U. The contact hole defined through the upper insulating layer IL-U may correspond to contact holes CNT-1, CNT-2, and CNT-3 described with reference to FIG. 5.

According to an embodiment, the first, second, and third group electrodes AE1, AE2, and AE3 may have different sizes from each other. As an example, the third group electrode AE3 may have a size smaller than that of the first group electrode AE1 and greater than that of the second group electrode AE2.

The first group electrode AE1 and the third group electrode AE3, which may be included in each of the i-th pixel row PXLᵢ and the (i+1)th pixel row PXLᵢ₊₁, may be disposed spaced apart from each other in the first direction DR1. The second group electrodes AE2 included in each of the i-th pixel row PXLᵢ and the (i+1)th pixel low PXLᵢ₊₁ may be arranged in the first direction DR1.

A second group electrode AE2 may be disposed between the first group electrode AE1 and the third group electrode AE3 and may be arranged with the first group electrode AE1 and the third group electrode AE3 in a fourth direction DR4 that may be an oblique direction of the first and second directions DR1 and DR2 or a fifth direction DR5 crossing the fourth direction DR4.

In the disclosure, the lower electrodes adjacent to each other among the lower electrodes AE may be referred to as a first lower electrode AE-1 and a second lower electrode AE-2. In FIG. 4, the lower electrode included in the first color pixel PX1 and the lower electrode included in the second color pixel PX2, which may be disposed adjacent to each other in the (i+1)th pixel low PXLᵢ₊₁, are illustrated as the first lower electrode AE-1 and the second lower electrode AE-2, respectively.

However, the first lower electrode AE-1 and the second lower electrode AE-2 are not particularly limited as long as they may be lower electrodes disposed adjacent to each other. Accordingly, descriptions on the first and second lower electrodes AE-1 and AE-2 may be applied to the lower electrodes AE disposed adjacent to each other regardless of the group of the lower electrodes AE.

The pixel definition layer PDL may be disposed on the upper insulating layer IL-U. The pixel definition layer PDL may include pixel definition patterns PDP arranged in the first direction DR1 and the second direction DR2.

Each of the pixel definition patterns PDP may be provided with one pixel opening OP-P through which a lower electrode of a corresponding group electrode among the first, second, and third group electrodes AE1, AE2, and AE3.

In a plan view, an outer side surface P-O of each of the pixel definition patterns PDP may have a rectangular shape extending in the first and second directions DR1 and DR2, and the inner side surface P-I of each of the pixel definition patterns PDP defining the pixel opening OP-P may have a lozenge shape extending in the fourth and fifth directions DR4 and DR5. However, the shape of the pixel definition patterns PDP is not particularly limited.

The first group electrode AE1 and the third group electrode AE3 may be disposed adjacent to an upper portion of the pixel definition pattern overlapping therewith in case compared with the second group electrode AE2. The second group electrode AE2 may be disposed adjacent to a lower portion of the pixel definition pattern overlapping therewith in case compared with the first group electrode AE1 and the third group electrode AE3.

However, the disclosure is not limited thereto or thereby. According to an embodiment, each of the first group electrodes AE1 and the third group electrodes AE3 may be disposed adjacent to the lower portion of the corresponding pixel definition pattern, and each of the second group electrodes AE2 may be disposed adjacent to the upper portion of the corresponding pixel definition pattern.

An area SP (hereinafter, referred to as a separation area) in which the pixel definition patterns PDP may be spaced apart from each other may have a grid shape extending in the first and second directions DR1 and DR2 in a plan view. However, the shape of the separation area SP is not particularly limited, and the shape of the separation area SP may be changed depending on the shape of each of the pixel definition patterns PDP.

As shown in FIG. 4, the pixel circuit CC of each of the pixels PX may be disposed not to overlap the separation area SP. This will be described in detail later.

In the disclosure, among the pixel definition patterns PDP, the pixel definition pattern surrounding the first lower electrode AE-1 may be defined as a first pixel definition pattern P1, and the pixel definition pattern surrounding the second lower electrode AE-2 may be defined as a second pixel definition pattern P2. The first and second pixel definition patterns P1 and P2 may also be disposed adjacent to each other.

In FIG. 4, the pixel definition pattern surrounding the first group electrode AE1 included in the (i+1)th pixel row PXLᵢ₊₁ is shown as the first pixel definition pattern P1, and the pixel definition pattern surrounding the second group electrode AE2 included in the (i+1)th pixel row PXLᵢ₊₁ is shown as the second pixel definition pattern P2.

However, the first pixel definition pattern P1 and the second pixel definition pattern P2 are not particularly limited as long as they may be the pixel definition patterns PDP disposed adjacent to each other. Accordingly, hereinafter, descriptions on the first and second pixel definition patterns P1 and P2 may be applied to the pixel definition patterns PDP disposed adjacent to each other regardless of the group of the lower electrodes AE.

In FIG. 4, the sacrificial layer SFL is shown with a dash-dotted line. The sacrificial layer SFL may be disposed on the upper insulating layer IL-U and may be covered by the pixel definition layer PDL.

The sacrificial layer SFL may include sacrificial patterns SFP arranged in the first direction DR1 and the second direction DR2. According to an embodiment, each of the sacrificial patterns SFP may be covered by a pixel definition pattern, however, embodiments are not limited thereto or thereby. Multiple sacrificial patterns may be covered by a single pixel definition pattern.

Each of the sacrificial patterns SFP may include a sacrificial opening OP-S. Each of the sacrificial openings OP-S may overlap at least a portion of a corresponding lower electrode among the first, second, and third group electrodes AE1, AE2, and AE3.

Each of the sacrificial openings OP-S may correspond to the pixel opening OP-P defined through the corresponding pixel definition pattern among the pixel definition patterns PDP. Each of the sacrificial openings OP-S may be defined to overlap the corresponding pixel opening OP-P. A size of each of the sacrificial openings OP-S may be greater than a size of the corresponding pixel opening OP-P.

In a plan view, an outer side surface S-O of each of the sacrificial patterns SFP may have a rectangular shape extending in the first and second directions DR1 and DR2, and an inner side surface S-I of each of the sacrificial patterns SFP may have a lozenge shape extending in the fourth and fifth directions DR4 and DR5. The shape of the sacrificial patterns SFP may correspond to the shape of the pixel definition patterns PDP.

However, the shape of the sacrificial patterns SFP is not particularly limited. As an example, the shape of the sacrificial patterns SFP may be changed to correspond to the shape of the pixel definition patterns PDP.

In the disclosure, among the sacrificial patterns SFP, a sacrificial pattern covered by the first pixel definition pattern P1 may be defined as a first sacrificial pattern 51, and a sacrificial pattern covered by the second pixel definition pattern P2 may be defined as a second sacrificial pattern S2.

In FIG. 4, the first sacrificial pattern S1 may surround the first group electrode AE1 included in the (i+1)th pixel row PXLᵢ₊₁, and the second sacrificial pattern S2 may surround the second group electrode AE2 included in the (i+1)th pixel row PXLᵢ₊₁.

FIG. 5 shows a cross-section of the display panel 100 in an area in which the first lower electrode AE-1 and the second lower electrode AE-2 defined in FIG. 4 may be disposed. For example, FIG. 5 shows a cross-section of the display panel 100 in an area in which the first group electrode AE1 and the second group electrode AE2 included in the (i+1)th pixel row PXLᵢ₊₁ may be disposed.

However, descriptions with reference to FIG. 5 may be applied to a cross-section of the display panel 100 in an area in which the third group electrode AE3 (refer to FIG. 4) included in the (1+1)th pixel row PXLᵢ₊₁ and the first, second, and third group electrodes AE1, AE2, and AE3 (refer to FIG. 4) included in other pixel rows may be disposed. Hereinafter, a structure in the cross-section of the display panel 100 will be described in detail with reference to FIG. 5.

Referring to FIG. 5, the display panel 100 may include the base layer 110, the circuit element layer 120, the light emitting element layer 130, and the encapsulation layer 140. The stack structure of the display panel 100 is not particularly limited.

The display panel DP may include insulating layers, a semiconductor pattern, a conductive pattern, and a signal line. An insulating layer, a semiconductor layer, and a conductive layer may be formed by a coating or depositing process in the manufacturing process of the display panel 100. The insulating layer, the semiconductor layer, and the conductive layer may be selectively patterned by a photolithography process. The semiconductor pattern, the conductive pattern, and the signal line included in the circuit element layer 120 and the light emitting element layer 130 may be formed through the above processes.

The base layer 110 may provide a base surface on which the circuit element layer 120 may be disposed. The base layer 110 may include a glass substrate, a metal substrate, a polymer substrate, an organic/inorganic composite material substrate, or a combination thereof.

The base layer 110 may have a multi-layer structure. For instance, the base layer 110 may include synthetic resin layers and at least one inorganic layer disposed between the synthetic resin layers. The synthetic resin layers of the base layer 110 may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin. However, the base layer 110 is not limited thereto or thereby.

At least one inorganic layer may be disposed on an upper surface of the base layer 110. The inorganic layers may form a barrier layer and/or a buffer layer. FIG. 5 shows a buffer layer BFL disposed on the base layer 110. The buffer layer BFL may increase an adhesion between the base layer 110 and the semiconductor pattern. The buffer layer BFL may include at least one of aluminum oxide, titanium oxide, silicon oxide, silicon nitride, silicon oxynitride, zirconium oxide, and hafnium oxide.

The semiconductor pattern of the circuit element layer 120 may be disposed on the buffer layer BFL. FIG. 5 shows a portion of the semiconductor pattern, and the semiconductor pattern may be arranged to overlap light emitting areas PXA described later in a plan view. The semiconductor pattern may include polysilicon, however, embodiments are not limited thereto or thereby. The semiconductor pattern may include amorphous silicon or oxide semiconductor.

The semiconductor pattern may have different electrical properties depending on whether it is doped or not or whether it is doped with an N-type dopant or a P-type dopant. The semiconductor pattern may include a first region having a relatively high conductivity and a second region having a relatively low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or a region doped at a concentration lower than that of the first region.

The first region may have a conductivity greater than that of the second region and may substantially serve as an electrode or a signal line. The second region may substantially correspond to an active area (or a channel area) of the transistor. In other words, a portion of the semiconductor pattern may be the active area of the transistor, and another portion of the semiconductor pattern may be a source area or a drain area of the transistor.

The circuit element layer 120 may include transistors TR, a connection signal line SCL, and insulating layers 10 to 60. The transistor TR may correspond to one of the first to seventh transistors T1 to T7 described with reference to FIG. 3B.

A source area S, an active area A, and a drain area D of the transistor TR may be formed from the semiconductor pattern. The connection signal line SCL may be formed from the semiconductor pattern and may be disposed on the same layer as a layer on which the source area S, the active area A, and the drain area D of the transistor TR may be disposed. The connection signal line SCL may be electrically connected to the drain area D of the transistor TR.

The insulating layers may be disposed on the buffer layer BFL. FIG. 5 shows first, second, third, fourth, fifth, and sixth insulating layers 10 to 60 as an example of the insulating layers. The first to sixth insulating layers 10 to 60 may be an inorganic layer and/or an organic layer. As an example, the inorganic layer may include at least one of aluminum oxide, titanium oxide, silicon oxide, silicon nitride, silicon oxynitride, zirconium oxide, and hafnium oxide.

The first insulating layer 10 may cover the semiconductor pattern of the circuit element layer 120. A gate electrode G of the transistor TR may be disposed on the first insulating layer 10. The gate electrode G may be a portion of the conductive pattern. The gate electrode G may overlap the active area A. The gate electrode G may serve as a mask in a process of doping the semiconductor pattern.

The second insulating layer 20 may be disposed on the first insulating layer 10 and may cover the gate electrode G. An upper electrode UE may be disposed on the second insulating layer 20. The upper electrode UE may overlap the gate electrode G.

The third insulating layer 30 may be disposed on the second insulating layer 20 and may cover the upper electrode UE. A first connection electrode CNE1 may be disposed on the third insulating layer 30. The first connection electrode CNE1 may be connected to the connection signal line SCL via a contact hole CNT-1 defined through the first to third insulating layers 10 to 30. The fourth insulating layer 40 may be disposed on the third insulating layer 30 and may cover the first connection electrode CNE1.

The fifth insulating layer 50 may be disposed on the fourth insulating layer 40. A second connection electrode CNE2 may be disposed on the fifth insulating layer 50. The second connection electrode CNE2 may be connected to the first connection electrode CNE1 via a contact hole CNT-2 defined through the fourth insulating layer 40 and the fifth insulating layer 50.

The sixth insulating layer 60 may be disposed on the fifth insulating layer 50 and may cover the second connection electrode CNE2. The sixth insulating layer 60 may correspond to the upper insulating layer IL-U described with reference to FIG. 4.

According to an embodiment, each of the fifth insulating layer 50 and the sixth insulating layer 60 may include an organic layer. The fifth insulating layer 50 and the sixth insulating layer 60 may provide a flat upper surface.

The light emitting element layer 130 may be disposed on the circuit element layer 120. The light emitting element layer 130 may include the light emitting elements LD and the pixel definition layer PDL.

Each of the light emitting elements LD may include the lower electrodes AE-1 and AE-2, light emitting layers EML1 and EML2, and an upper electrode CE. According to an embodiment, the lower electrodes AE-1 and AE-2 may be included in each of the light emitting elements LD.

In an embodiment, the light emitting elements LD may include a first light emitting element LD-1 and a second light emitting element LD-2. The first light emitting element LD-1 may be defined as the light emitting element including the first lower electrode AE-1, and the second light emitting element LD-2 may be defined as the light emitting element including the second lower electrode AE-2.

Each of the first lower electrode AE-1 and the second lower electrode AE-2 may be disposed on the sixth insulating layer 60. Each of the first lower electrode AE-1 and the second lower electrode AE-2 may be connected to the second connection electrode CNE2 via a contact hole CNT-3 defined through the sixth insulating layer 60.

The sacrificial layer SFL may be disposed between the sixth insulating layer 60 and the pixel definition layer PDL. In an embodiment, the sacrificial layer SFL may include the first sacrificial pattern S1 and the second sacrificial pattern S2.

According to an embodiment, at least a portion of the first sacrificial pattern S1 may cover at least a portion of an end area of the first lower electrode AE-1. At least a portion of the second sacrificial pattern S2 may cover at least a portion of an end area of the second lower electrode AE-2.

The first sacrificial pattern S1 may include a first-first side surface SS1-1 that defines a sacrificial opening OP-S of the first sacrificial pattern S1. The second sacrificial pattern S2 may include a first-second side surface SS1-2 that defines the sacrificial opening OP-S of the second sacrificial pattern S2. The first-first side surface SS1-1 and the first-second side surface SS1-2 may correspond to the inner side surface S-I of each of the sacrificial patterns SFP described with reference to FIG. 4.

The first sacrificial pattern S1 may include a second side surface SS2 opposite to the first-first side surface SS1-1. The second side surface SS2 may be spaced farther from the first lower electrode AE-1 than the first-first side surface SS1-1 is.

The second sacrificial pattern S2 may include a third side surface SS3 opposite to the first-second side surface SS1-2. The third side surface SS3 may be spaced farther from the second lower electrode AE-2 than the first-second side surface SS1-2 is.

A portion of the second side surface SS2 and a portion of the third side surface SS3 may face each other. The second side surface SS2 and the third side surface SS3 may correspond to the outer side surface S-O of each of the sacrificial patterns SFP described with reference to FIG. 4.

The first-first side surface SS1-1 of the first sacrificial pattern S1 may be inclined with respect to the first lower electrode AE-1 at an angle. The first-second side surface SS1-2 of the second sacrificial pattern S2 may be inclined with respect to the second lower electrode AE-2 at the angle. Each of the second side surface SS2 of the first sacrificial pattern S1 and the third side surface SS3 of the second sacrificial pattern S2 may be inclined with respect to an upper surface of the sixth insulating layer 60 at the angle.

According to an embodiment, the sacrificial layer SFL may include an inorganic material. As an example, the sacrificial layer SFL may include at least one of indium zinc oxide (IZO), indium gallium zinc oxide (IGZO), titanium (Ti), and indium-doped zinc oxide (ZIO), however, materials for the sacrificial layer SFL are not limited thereto or thereby. As an example, various materials may be applied to the sacrificial layer SFL as long as the materials may be deposited by a sputtering process or a chemical vapor deposition (CVD) process.

According to an embodiment, as the sacrificial layer SFL includes the inorganic material, an adhesion between the sacrificial layer SFL and the lower electrodes AE (refer to FIG. 4) may be improved. Accordingly, the sacrificial layer SFL may be prevented from being separated from the end area of each of the lower electrodes AE (refer to FIG. 4). The chemical damages of the lower electrodes AE (refer to FIG. 4) caused by the exposure of the end area of each of the lower electrodes AE (refer to FIG. 4) during the manufacturing process of the display panel 100 may be prevented, and thus, the display panel 100 may be prevented from being damaged by external impacts.

However, embodiments are not limited thereto or thereby, and the sacrificial layer SFL may include a metal material. According to an embodiment, as the sacrificial layer SFL may include the sacrificial patterns SFP spaced apart from each other, the first lower electrode AE-1 and the second lower electrode AE-2 may be prevented from being electrically connected to each other by the sacrificial layer SFL even though the sacrificial layer SFL includes the metal material.

The pixel definition layer PDL may be disposed on the sixth insulating layer 60 and may cover the sacrificial layer SFL. In an embodiment, the pixel definition layer PDL may include the first pixel definition pattern P1 that covers the first sacrificial pattern Si and the second pixel definition pattern P2 that covers the second sacrificial pattern S2.

The first pixel definition pattern P1 may cover the first-first side surface SS1-1 and the second side surface SS2 of the first sacrificial pattern S1. The second pixel definition pattern P2 may cover the first-second side surface SS1-2 and the third side surface SS3 of the second sacrificial pattern S2.

The sacrificial opening OP-S defined by the first-first side surface SS1-1 of the first sacrificial pattern Si may have a size greater than a size of the pixel opening OP-P that overlaps the sacrificial opening OP-S and may be defined through the first pixel definition pattern P1. Accordingly, at least a portion of the first lower electrode AE-1 may be exposed through the sacrificial opening OP-S without being covered by the first pixel definition pattern P1.

The sacrificial opening OP-S defined by the first-second side surface SS1-2 of the second sacrificial pattern S2 may have a size greater than a size of the pixel opening OP-P that overlaps the sacrificial opening OP-S and may be defined through the second pixel definition pattern P2. Accordingly, at least a portion of the second lower electrode AE-2 may be exposed through the sacrificial opening OP-S without being covered by the second pixel definition pattern P2.

In an embodiment, the light emitting areas PXA may correspond to a portion of each of the lower electrodes AE (refer to FIG. 4) exposed through the pixel openings OP-P. As shown in FIG. 5, each of a portion of the first lower electrode AE-1 exposed through the pixel opening OP-P of the first pixel definition pattern P1 and a portion of the second lower electrode AE-2 exposed through the pixel opening OP-P of the second pixel definition pattern P2 may define the light emitting area PXA. A non-light-emitting area NPXA may correspond to an area except the light emitting areas PXA and may surround the light emitting areas PXA.

The pixel definition layer PDL may include an organic material. The pixel definition layer PDL may include a light blocking material and may have a black color. As an example, the pixel definition layer PDL may include a base resin and a coloring material mixed with the base resin. As an example, the base resin may include at least one of an acrylic-based resin, a polyimide-based resin, and a siloxane-based resin. The coloring material may include a black pigment and/or a black dye. The coloring material may include a metal material, such as at least one of carbon black, chromium, and an oxide thereof.

According to an embodiment, the pixel definition layer PDL may have an optical density equal to or greater than about 1.0. In an embodiment, the optical density of the pixel definition layer PDL may be equal to or greater than about 1.5. The optical density of the pixel definition layer PDL may be proportional to a content ratio of the coloring material. For example, as the content ratio of the black pigment and/or the black dye of the pixel definition layer PDL increases, the optical density of the pixel definition layer PDL may increase.

As the optical density of the pixel definition layer PDL increases, the external light may be prevented from being reflected by lines disposed under the light emitting element layer 130. Accordingly, a deterioration in visibility due to the reflection of the external light may be prevented by the pixel definition layer PDL even though a separate anti-reflective film may not be attached onto the display panel 100. According to an embodiment, as the anti-reflective film that causes a deterioration in a flexible performance of the display device DD (refer to FIG. 1A) may not be attached, the flexible performance of the display device DD (refer to FIG. 1A) may be improved.

However, as the content ratio of the black pigment and/or the black dye of the pixel definition layer PDL increases to enhance the optical density of the pixel definition layer PDL, residual particles formed from the black pigment and/or black dye may remain on the lower electrodes AE (refer to FIG. 4) in the patterning process of the pixel definition layer PDL. Accordingly, some of the lower electrodes AE (refer to FIG. 4) may be short-circuited, and the light may not be provided from some of the light emitting elements LD.

As the content ratio of the black pigment and/or the black dye of the pixel definition layer PDL increases to enhance the optical density of the pixel definition layer PDL, a transmittance of the pixel definition layer PDL may be lowered. In the patterning process of the pixel definition layer PDL, the pixel definition layer PDL may not be sufficiently exposed to the light. Accordingly, due to the insufficient etching of the pixel definition layer PDL, a fine residual layer may remain on the lower electrodes AE (refer to FIG. 4). Accordingly, the luminance of the light provided from the light emitting elements LD may be reduced, and a luminance lifetime may be reduced.

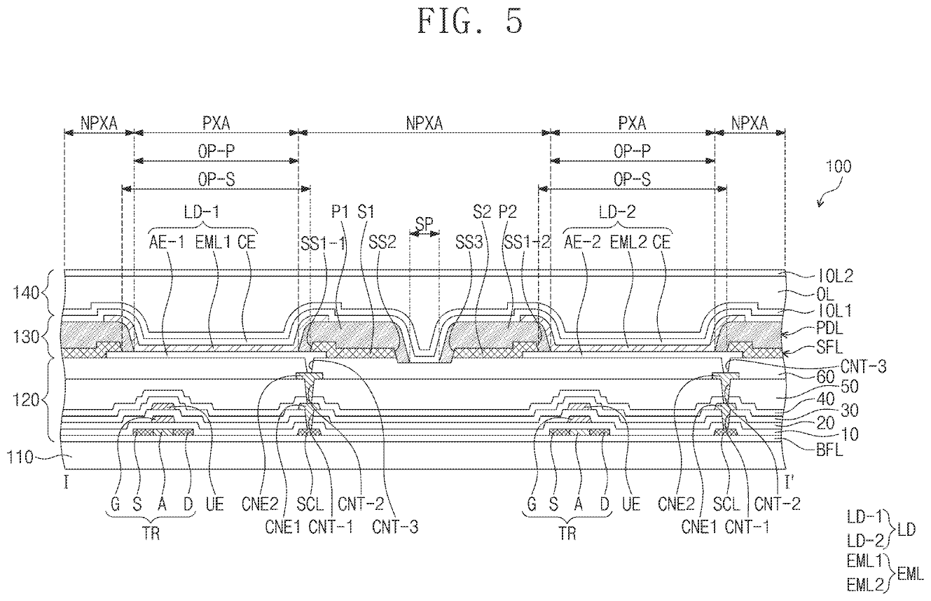

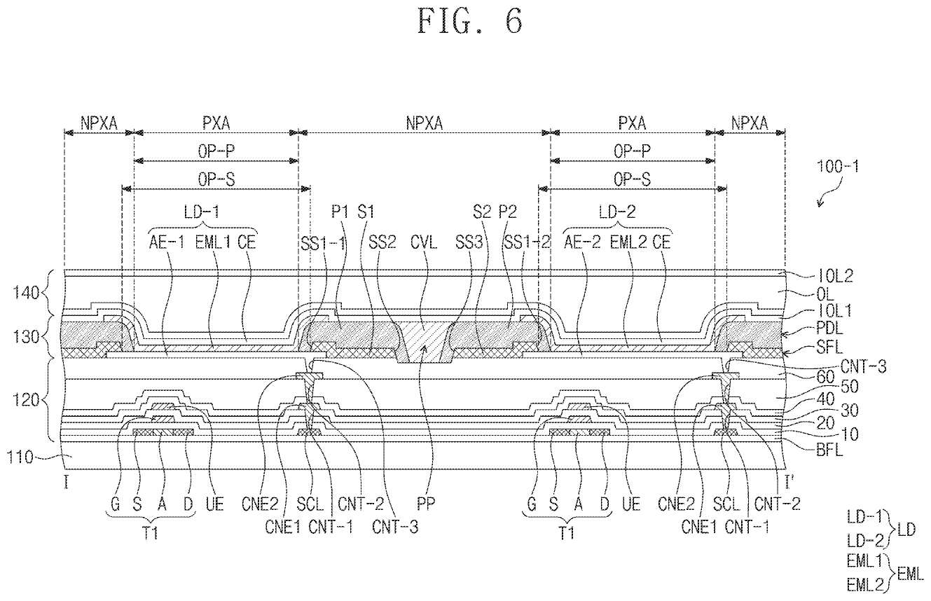

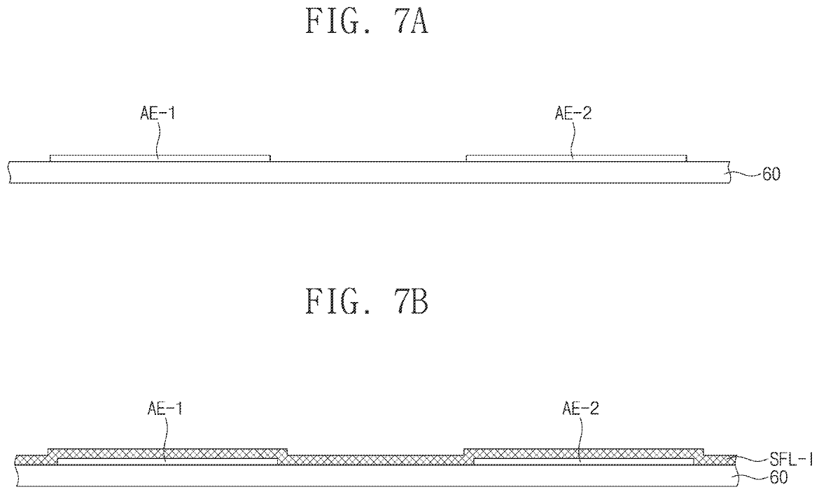

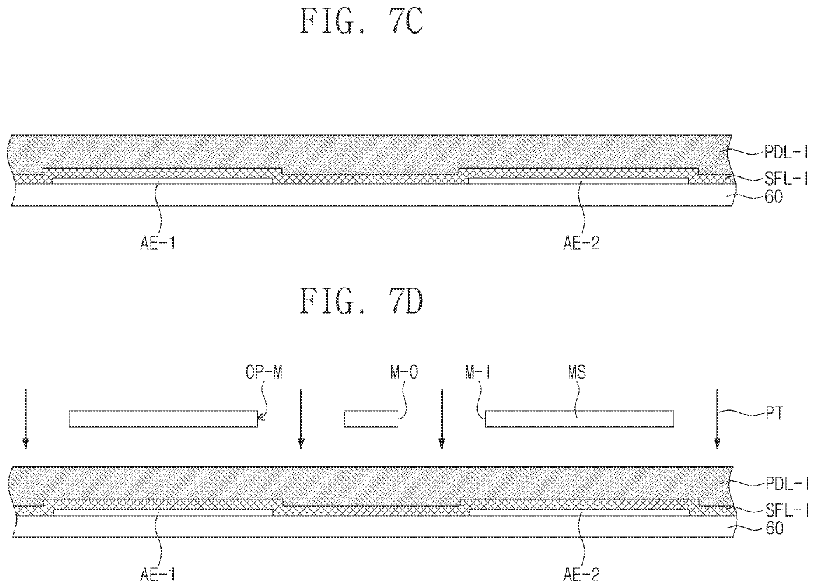

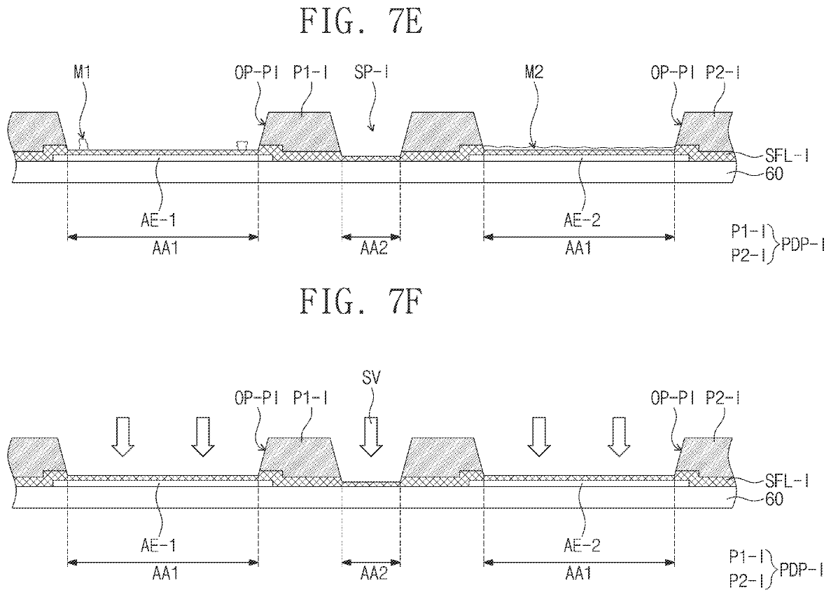

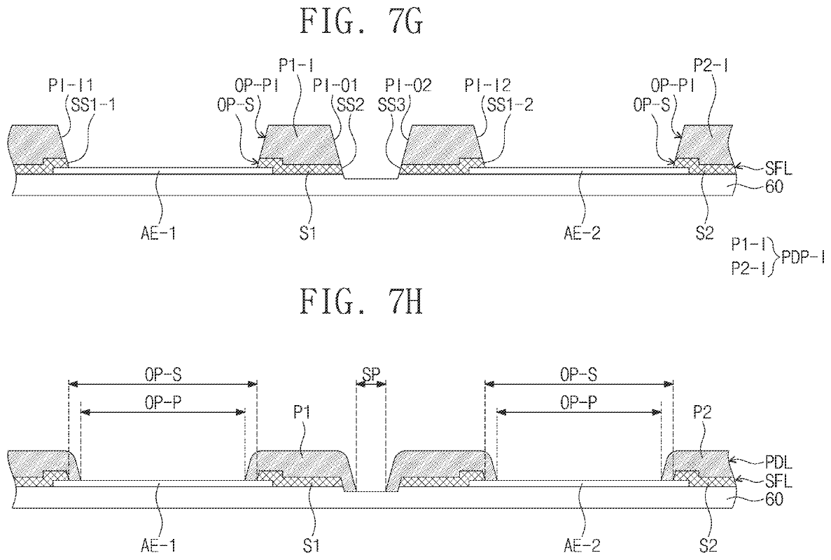

According to the disclosure, as the sacrificial layer SFL may be disposed between the lower electrodes AE (refer to FIG. 4) and the pixel definition layer PDL, the residual particles and/or the fine residual layer may be removed in a process of patterning the sacrificial layer SFL using the pixel definition layer PDL as a mask. Accordingly, defects, such as a formation of unlit pixels or a reduction of the luminance lifetime, may be prevented in the display device DD (refer to FIG. 1A). These will be described in detail with reference to FIGS. 7A to 7H showing the manufacturing method of the display device DD (refer to FIG. 1A).

According to an embodiment, the transistors T1 to T7 (refer to FIG. 3B) of the driving circuit CC (refer to FIG. 3B) may be disposed not to overlap the separation area SP between the pixel definition patterns PDP. Accordingly, the external light irradiated to the transistors T1 to T7 (refer to FIG. 3B) may be completely blocked, and thus, the reflection of the external light, which may be caused by the transistors T1 to T7 (refer to FIG. 3B), may not be generated.

According to an embodiment, the sacrificial layer SFL may include a material with a high surface energy to allow the pixel definition layer PDL and the sacrificial layer SFL to have a high adhesion. A surface energy between an organic layer of the definition layer PDL and an inorganic layer of the sacrificial layer SFL may increase, and thus, the adhesion between the sacrificial layer SFL and the pixel definition layer PDL may increase. Accordingly, the damage of the sacrificial layer SFL, which may be caused by the exposure due to the detachment of the pixel definition layer PDL from the sacrificial layer SFL, may be prevented.

The light emitting layer EML may be disposed on the lower electrodes AE (refer to FIG. 4). The light emitting layer EML may be disposed in areas respectively corresponding to the pixel openings OP-P of each of the first pixel definition pattern P1 and the second pixel definition pattern P2.

The light emitting layer EML may be disposed in the light emitting areas PXA after being divided into multiple portions. As an example, a first color light emitting layer EML1, a second color light emitting layer EML2, and a third color light emitting layer (not shown) may be respectively disposed on the first group electrode AE1, the second group electrode AE2, and the third group electrode AE3 described with reference to FIG. 4. FIG. 5 shows only the first color light emitting layer EML1 disposed on the first lower electrode AE-1 and the second color light emitting layer EML2 disposed on the second lower electrode AE-2.

In an embodiment, the first color light emitting layer EML1, the second color light emitting layer EML2, and the third color light emitting layer (not shown) may provide lights having different colors from each other. As an example, each of the first color light emitting layer EML1, the second color light emitting layer EML2, and the third color light emitting layer (not shown) may emit at least one color light among blue, green, and red lights.

According to an embodiment, the first color light emitting layer EML1 may emit the blue light, the second color light emitting layer EML2 may emit the green light, and the third color light emitting layer (not shown) may emit the red light. Accordingly, the first color light provided by the first color pixel PX1 (refer to FIG. 4) including the first color light emitting layer EML1 may be the blue light. The second color light provided by the second color pixel PX2 (refer to FIG. 4) including the second color light emitting layer EML2 may be the green light. The third color light provided by the third color pixel PX3 (refer to FIG. 4) including the third color light emitting layer (not shown) may be the red light.

However, embodiments are not limited thereto or thereby, and the light emitting layer EML may be commonly provided in the light emitting areas PXA and may emit the blue light or a white light.

The light emitting layer EML may include at least one of an organic light emitting material, an inorganic light emitting material, a quantum dot, or a quantum rod.

The upper electrode CE may be disposed on the light emitting layer EML. The upper electrode CE may be commonly disposed in the light emitting areas PXA and the non-light-emitting area NPXA. The upper electrode CE may have an integral shape and may be commonly disposed in the pixels PX (refer to FIG. 4). A common voltage may be provided to the upper electrode CE, and the upper electrode CE may be referred to as a common electrode.

According to the disclosure, as the pixel definition layer PDL may cover the side surfaces SS1-1, SS1-2, SS2, and SS3 of the sacrificial layer SFL, the lower electrodes AE and the upper electrode CE may be prevented from being electrically connected to each other.

Although not shown in FIG. 5, the light emitting elements LD may further include a hole control layer between the lower electrodes AE-1 and AE-2 and the light emitting layers EML1 and EML2 and an electron control layer between the light emitting layers EML1 and EML2 and the upper electrode CE.

Each of the hole control layer and the electron control layer may be commonly disposed in the light emitting areas PXA and the non-light-emitting area NPXA. The hole control layer may include at least one of a hole transport layer and a hole injection layer. The electron control layer may include at least one of an electron transport layer and an electron injection layer.

The encapsulation layer 140 may be disposed on the light emitting element layer 130.

According to an embodiment, the encapsulation layer 140 may include a first inorganic layer IOL1 disposed on the upper electrode CE of the light emitting element layer 130, an organic layer OL disposed on the first inorganic layer IOL1, and a second inorganic layer IOL2 disposed on the organic layer OL. However, the configuration and arrangement of the encapsulation layer 140 are not particularly limited.

The first and second inorganic layers IOL1 and IOL2 may protect the light emitting element layer 130 from moisture and/or oxygen. The organic layer OL may protect the light emitting element layer 130 from a foreign substance, such as dust particles.

FIG. 6 is a schematic cross-sectional view of a display panel 100-1 to correspond to line I-I′ of FIG. 4. In FIG. 6, the same/similar reference numerals denote the same/similar elements in FIGS. 1A to 5, and thus, detailed descriptions of the same/similar elements will be omitted.

Referring to FIG. 6, a display panel 100-1 may further include a cover layer CVL. The cover layer CVL may be disposed in a separation space PP between pixel definition patterns PDP.

According to an embodiment, as the separation space PP between the pixel definition patterns PDP may be filled with the cover layer CVL, a flat surface may be provided between the pixel definition patterns PDP. Accordingly, an upper electrode CE disposed on the pixel definition patterns PDP may be disposed without bending by the cover layer CVL. Accordingly, the upper electrode CE may be prevented from being bent and disconnected, and an increase in resistance of the upper electrode CE due to an increase of a length of the upper electrode CE may be prevented.

According to an embodiment, the cover layer CVL may include an organic material. As an example, the cover layer CVL may include a photosensitive polyimide, however, embodiments are not limited thereto or thereby. The cover layer CVL may include a light blocking material and may have a black color. As an example, the cover layer CVL may include a base resin and a coloring material mixed with the base resin. As an example, the base resin may include at least one of an acrylic-based resin, a polyimide-based resin, and a siloxane-based resin. The coloring material may include a black pigment and/or a black dye.

FIGS. 7A to 7H are schematic cross-sectional views of a method of manufacturing a display device according to an embodiment of the disclosure. Hereinafter, the same/similar reference numerals denote the same/similar elements in FIGS. 1A to 6, and thus, detailed descriptions of the same/similar elements will be omitted in describing the manufacturing method of the display device DD (refer to FIG. 1A) with reference to FIGS. 7A to 7H.

FIGS. 7A to 7H schematically show only the sixth insulating layer 60 of the circuit element layer 120 (refer to FIG. 5) among the components of the display panel 100 (refer to FIG. 5). The base layer 110 (refer to FIG. 5), the transistor TR (refer to FIG. 5) of the circuit element layer 120 (refer to FIG. 5), and the first to fifth insulating layers 10 to 50 (refer to FIG. 5), which may be disposed under the sixth insulating layer 60 may be omitted.

Referring to FIGS. 7A and 7B, the manufacturing method of the display device DD (refer to FIG. 1A) may include forming a preliminary sacrificial layer SFL-I on the sixth insulating layer 60 on which the first lower electrode AE-1 and the second lower electrode AE-2 spaced apart from first lower electrode AE-1 may be disposed.

The preliminary sacrificial layer SFL-I may be formed through a deposition process. According to an embodiment, the preliminary sacrificial layer SFL-I may be formed through a physical vapor deposition (PVD) process. As an example, the preliminary sacrificial layer SFL-I may be formed by a sputtering process. According to an embodiment, the preliminary sacrificial layer SFL-I may be formed by a chemical vapor deposition (CVD) process.

The preliminary sacrificial layer SFL-I formed by the deposition process may be disposed on the sixth insulating layer 60 and may cover the first and second lower electrodes AE-1 and AE-2 as shown in FIG. 7B.

Referring to FIG. 7C, the manufacturing method of the display device DD (refer to FIG. 1A) may include forming a light blocking layer PDL-I on the preliminary sacrificial layer SFL-I.

The light blocking layer PDL-I may include a light blocking material. As an example, the light blocking layer PDL-I may include the base resin and the coloring material mixed with the base resin. According to an embodiment, the optical density of the light blocking layer PDL-I may be equal to or greater than about 1.0.

According to an embodiment, the light blocking layer PDL-I may be formed by a spin coating method. However, the coating method of the light blocking layer PDL-I is not particularly limited.

The coated light blocking layer PDL-I may be disposed on the preliminary sacrificial layer SFL-I and may provide a flat upper surface as shown in FIG. 7C. In the disclosure, the light blocking layer PDL-I may be formed as the pixel definition layer PDL later.

Referring to FIGS. 7D and 7E, the manufacturing method of the display device DD (refer to FIG. 1A) may include patterning the light blocking layer PDL-I.

Referring to FIG. 7D, a mask MS through which openings OP-M may be defined may be disposed on the light blocking layer PDL-I, and a light PT may be irradiated onto the light blocking layer PDL-I.

According to an embodiment, the openings OP-M may be defined to overlap the pixel definition patterns PDP formed later. In detail, in a plan view, an outer side surface M-O of the openings OP-M may have a rectangular shape extending in the first and second directions DR1 and DR2 (refer to FIG. 4), and an inner side surface M-I of the openings OP-M may have a lozenge shape extending in the fourth and fifth directions DR4 and DR5 (refer to FIG. 4).

In FIG. 7D, since the light blocking layer PDL-I may include a negative resist, portions of the light blocking layer PDL-I, which may be exposed to the light PT, may be cured, and portions of the light blocking layer PDL-I, which may not be exposed to the light PT, may be removed.

However, the property of the light blocking layer PDL-I is not limited thereto or thereby, and according to an embodiment, the light blocking layer PDL-I may include a positive resist. Portions of the light blocking layer PDL-I, which may be exposed to the light PT, may be removed. The mask used to pattern the light blocking layer PDL-I may be provided with the openings OP-M defined therethrough to overlap the pixel openings OP-P (refer to FIG. 4) that are to be defined through the light blocking layer PDL-I.

In detail, the openings OP-M defined through the mask may include openings each having a lozenge shape extending in the fourth and fifth directions DR4 and DR5 (refer to FIG. 4) and may include an opening having a grid shape extending in the first and second directions DR1 and DR2 (refer to FIG. 4) to surround each of the openings.

Referring to FIG. 7E, a development process may be performed on the light blocking layer PDL-I, and thus, the portions to which the light PT (refer to FIG. 7D) may not be irradiated may be removed.

The portions of the light blocking layer PDL-I may be removed, and preliminary pixel definition patterns PDP-I spaced apart from each other may be formed. A preliminary pixel opening OP-PI may be formed through each of the preliminary pixel definition patterns PDP-I.

According to an embodiment, the preliminary pixel definition patterns PDP-I may include a first preliminary pixel definition pattern P1-I disposed on the first lower electrode AE-1 and a second preliminary pixel definition pattern P2-I disposed on the second lower electrode AE-2.

According to an embodiment, a side surface of each of the first preliminary pixel definition pattern P1-I and the second preliminary pixel definition pattern P2-I may be formed to be inclined with respect to the sixth insulating layer 60 at the angle.

Areas AA1 (hereinafter, referred to as first areas) of the preliminary sacrificial layer SFL-I, which respectively overlap portions of the first and second lower electrodes AE-1 and AE-2, may be exposed through the preliminary pixel openings OP-PI. An area AA2 (hereinafter, referred to as a second area) of the preliminary sacrificial layer SFL-I, which overlaps a separation area SP-I between the first preliminary pixel definition pattern P1-I and the second preliminary pixel definition pattern P2-I, may be exposed.

According to an embodiment, as shown in FIG. 7E, a portion of the preliminary sacrificial layer SFL-I may be removed along the third direction DR3 in the first areas AA1 and the second area AA2 of the preliminary sacrificial layer SFL-I. Accordingly, a thickness of the preliminary sacrificial layer SFL-I in the first areas AA1 and the second area AA2 may be smaller than that of another area of the preliminary sacrificial layer SFL-I.

In the disclosure, as the light blocking layer PDL-I includes the light blocking material, the residual particles M1 and/or the fine residual layer M2 may be formed in the first areas AA1 of the preliminary sacrificial layer SFL-I after the light blocking layer PDL-I may be patterned.

Referring to FIGS. 7F and 7G, the manufacturing method of the display device DD (refer to FIG. 1A) may include etching the preliminary sacrificial layer SFL-I using the patterned light blocking layer PDL-I (refer to FIG. 7D) as a mask. The patterned light blocking layer PDL-I may correspond to the preliminary pixel definition patterns PDP-I in FIG. 7F. In an embodiment, the sacrificial layer SFL described with reference to FIGS. 5 and 6 may be formed by etching the preliminary sacrificial layer SFL-I. The sacrificial layer SFL may include the sacrificial patterns SFP (refer to FIG. 4).

Due to the preliminary pixel openings OP-PI, the preliminary sacrificial layer SFL-I may be etched in the first areas AA1, and thus, the sacrificial openings OP-S may be formed through the sacrificial layer SFL. Due to the separation area SP-I (refer to FIG. 7E) between the first and second preliminary pixel definition patterns P1-I and P2-I, the preliminary sacrificial layer SFL-I may be etched in the second area AA2, and thus, the first sacrificial pattern 51 and the second sacrificial pattern S2 spaced apart from the first sacrificial pattern 51 may be formed.

The first-first side surface SS1-1 of the first sacrificial pattern 51 may be aligned with an inner side surface PI-I1 that defines the preliminary pixel opening OP-PI of the first preliminary pixel definition pattern P1-I. The first-second side surface SS1-2 of the second sacrificial pattern S2 may be aligned with an inner side surface PI-12 that defines the preliminary pixel opening OP-PI of the second preliminary pixel definition pattern P2-I.

The second side surface SS2 of the first sacrificial pattern 51 may be aligned with an outer side surface PI-O1 of the first preliminary pixel definition pattern P1-I, and the third side surface SS3 of the second sacrificial pattern S2 may be aligned with an outer side surface PI-O2 of the second preliminary pixel definition pattern P2-I.

According to an embodiment, the portion of the sixth insulating layer 60, which overlaps the second area AA2 of the etched preliminary sacrificial layer SFL-I, may be exposed. The portion of the sixth insulating layer 60 in the exposed area may be removed in the third direction DR3. Accordingly, the sixth insulating layer 60 in the exposed area may have a thickness smaller than that of the sixth insulating layer 60 in another area.

According to an embodiment, the sacrificial layer SFL may be formed through a wet etching process. A solution SV that may be able to remove the preliminary sacrificial layer SFL-I may be provided to the first areas AA1 and the second area AA2 of the preliminary sacrificial layer SFL-I.

According to an embodiment, the preliminary sacrificial layer SFL-I may be removed in the first areas AA1, and thus, the sacrificial openings OP-S may be formed. Accordingly, the residual particles M1 and/or the fine residual layer M2 formed on the preliminary sacrificial layer SFL-I may be removed.

In a case where the sacrificial layer SFL may not be disposed between the lower electrodes AE-1 and AE-2 and the pixel definition layer PDL, the residual particles M1 and/or the fine residual layer M2 may be formed on the lower electrodes AE-1 and AE-2. The residual particles M1 and/or the fine residual layer M2 may be irregularly formed, and thus, the residual particles M1 and/or the fine residual layer M2 may be removed incompletely according to the degree of etching. Accordingly, defects, such as the formation of the unlit pixels or the reduction of the luminance lifetime, may be generated in the display panel 100 (refer to FIG. 2).

However, according to the disclosure, the preliminary sacrificial layer SFL-I may be formed at a thickness, and the degree of etching may be readily controlled by taking into account the thickness of the preliminary sacrificial layer SFL-I. Accordingly, as the preliminary sacrificial layer SFL-I may be partially removed, most of the residual particles M1 and/or the fine residual layer M2 formed on the preliminary sacrificial layer SFL-I may be removed. Accordingly, defects, such as the formation of the unlit pixels or the reduction of the luminance lifetime, may not be generated in the display panel 100 (refer to FIG. 2), and the reliability of the display panel 100 (refer to FIG. 2) may be improved.

According to the disclosure, the material constituting the sacrificial layer SFL may be determined by a selectivity. The selectivity may mean a ratio of an etch rate of the sacrificial layer SFL with respect to the etch rate of the lower electrodes AE-1 and AE-2. In an embodiment, the etch rate of the sacrificial layer SFL may be faster than the etch rate of the lower electrodes AE-1 and AE-2. As the etch rate of the sacrificial layer SFL becomes faster than the etch rate of the lower electrodes AE-1 and AE-2, i.e., as the selectivity of the sacrificial layer SFL with respect to the lower electrodes AE-1 and AE-2 becomes higher, selectively etching only the sacrificial layer SFL disposed on the lower electrodes AE-1 and AE-2 may be more readily performed. As the etch rate of the sacrificial layer SFL becomes faster, a time for the etching process of the sacrificial layer SFL may be reduced, and thus, the processes may be carried out economically.

Referring to FIG. 7H, the manufacturing method of the display device DD (refer to FIG. 1A) may include heat-treating the preliminary pixel definition patterns PDP-I (refer to FIG. 7G). In an embodiment, the preliminary pixel definition patterns PDP-I may be heat-treated, and the pixel definition layer PDL described with reference to FIGS. 5 and 6 may be formed. The pixel definition layer PDL may include the pixel definition patterns PDP (refer to FIG. 4).

In case that heat is provided, each of the preliminary pixel definition patterns PDP-I may be partially melted or a viscosity of the preliminary pixel definition patterns PDP-I may decrease, and as a result, the preliminary pixel definition patterns PDP-I may flow down along the side surface of each of the sacrificial patterns SFP. Accordingly, the pixel definition layer PDL formed after the heat-treating process may cover the corresponding sacrificial pattern.

The pixel definition patterns PDP (refer to FIG. 4) may include the first pixel definition pattern P1 formed from the first preliminary pixel definition pattern P1-I and the second pixel definition pattern P2 formed from the second preliminary pixel definition pattern P2-I.

The first pixel definition pattern P1 may cover the first sacrificial pattern S1. The first pixel definition pattern P1 may cover the first-first side surface SS1-1 and the second side surface SS2 of the first sacrificial pattern S1. The second pixel definition pattern P2 may cover the second sacrificial pattern S2. The second pixel definition pattern P2 may cover the first-second side surface SS1-2 and the third side surface SS3 of the second sacrificial pattern S2.

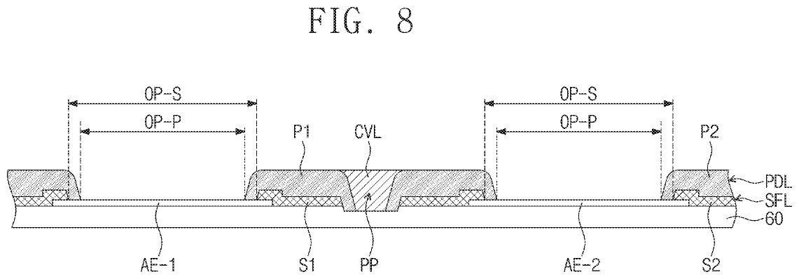

FIG. 8 is a schematic cross-sectional view of a method of manufacturing the display device DD (refer to FIG. 1A) according to an embodiment of the disclosure. The display device DD (refer to FIG. 1A) according to an embodiment of FIG. 6 may be manufactured by performing additional processes on the sacrificial layer SFL and the pixel definition layer PDL formed in FIG. 7H. FIG. 8 shows the additional processes. In FIG. 8, the same/similar reference numerals denote the same/similar elements in FIGS. 1A to 7H, and thus, detailed descriptions of the same/similar elements will be omitted.

Referring to FIG. 8, the manufacturing method of the display device DD (refer to FIG. 1A) may further include forming the cover layer CVL after the heat-treating of the preliminary pixel definition patterns PDP-I (refer to FIG. 7G) described with reference to FIG. 7H.

The cover layer CVL may be coated to cover the separation space PP between the first pixel definition pattern P1 and the second pixel definition pattern P2.

As shown in FIG. 8, the cover layer CVL may be formed to entirely cover the separation space PP, and the cover layer CVL may be aligned with an upper surface of the first pixel definition pattern P1 and an upper surface of the second pixel definition pattern P2, however, embodiments are not limited thereto or thereby. According to an embodiment, the cover layer CVL may cover only a portion of the separation space PP, or the cover layer CVL may be provided in the form of a single layer to entirely cover the separation spaces PP between the pixel definition patterns PDP (refer to FIG. 4) and the pixel definition patterns PDP (refer to FIG. 4).

Although embodiments of the disclosure have been described, it is understood that the disclosure is not limited to these embodiments but various changes and modifications can be made by one of ordinary skill in the art within the spirit and scope of the disclosure.

Therefore, the disclosed subject matter is not limited to any single embodiment described herein, and the scope of the disclosure shall be determined according to this description.

What is claimed is:

1. A display device comprising:
an insulating layer disposed on a base layer;
a first lower electrode disposed on the insulating layer;
a second lower electrode disposed on the insulating layer and spaced apart from the first lower electrode;
a pixel definition layer disposed on the insulating layer and including pixel openings exposing at least a portion of each of the first lower electrode and the second lower electrode; and
a sacrificial layer disposed between the pixel definition layer and the insulating layer and comprising a first side surface defining sacrificial openings corresponding to the pixel openings,
wherein the first side surface is overlapped by the pixel definition layer in a plan view.

2. The display device of claim 1, wherein
the sacrificial layer comprises:
a first sacrificial pattern adjacent to the first lower electrode; and
a second sacrificial pattern adjacent to the second lower electrode and spaced apart from the first sacrificial pattern, and the sacrificial openings comprise:
a first sacrificial opening defined in the first sacrificial pattern and exposing the at least the portion of the first lower electrode; and
a second sacrificial opening defined in the second sacrificial pattern and exposing the at least the portion of the second lower electrode.

3. The display device of claim 2, wherein the pixel definition layer comprises:
a first pixel definition pattern overlapping the first sacrificial pattern in a plan view; and
a second pixel definition pattern overlapping the second sacrificial pattern in a plan view and spaced apart from the first pixel definition pattern.

4. The display device of claim 3, wherein
the first sacrificial pattern comprises a second side surface facing the first side surface of the first sacrificial pattern and spaced farther from the first lower electrode than the first side surface of the first sacrificial pattern is,
the second sacrificial pattern comprises a third side surface facing the first side surface of the second sacrificial pattern and spaced farther from the second lower electrode than the first side surface of the second sacrificial pattern is,
the second side surface is overlapped by the first pixel definition pattern in a plan view,
the third side surface is overlapped by the second pixel definition pattern in a plan view, and
at least a portion of the second side surface faces at least a portion of the third side surface.

5. The display device of claim 3, further comprising:
a cover layer overlapping a separation space between the first pixel definition pattern and the second pixel definition pattern in a plan view and comprising an organic material.

6. The display device of claim 5, wherein the cover layer further comprises a light blocking material.

7. The display device of claim 1, wherein the pixel definition layer comprises a light blocking material.

8. The display device of claim 1, wherein the pixel definition layer has an optical density equal to or greater than about 1.0.

9. The display device of claim 1, wherein an etch rate of the sacrificial layer is faster than an etch rate of each of the first and second lower electrodes.

10. The display device of claim 1, wherein at least a portion of the sacrificial layer overlaps at least a portion of an end area of each of the first and second lower electrodes in a plan view.

11. A display device comprising:
a first light emitting element comprising a lower electrode, an upper electrode, and a light emitting layer disposed between the lower electrode and the upper electrode;
a second light emitting element comprising a lower electrode, an upper electrode, and a light emitting layer disposed between the lower electrode and the upper electrode;
transistors electrically connected to the lower electrode of the first light emitting element and the lower electrode of the second light emitting element;
a first pixel definition pattern including a first pixel opening through which at least a portion of the lower electrode of the first light emitting element is exposed;
a second pixel definition pattern including a second pixel opening through which at least a portion of the lower electrode of the second light emitting element is exposed;
a first sacrificial pattern overlapped by the first pixel definition pattern in a plan view; and
a second sacrificial pattern overlapped by the second pixel definition pattern and spaced apart from the first sacrificial pattern in a plan view,
wherein the transistors do not overlap an area between the first pixel definition pattern and the second pixel definition pattern, in a plan view.

12. The display device of claim 11, wherein each of the first pixel definition pattern and the second pixel definition pattern comprises a light blocking material.

13. The display device of claim 11, further comprising:
a cover layer overlapping a separation space between the first pixel definition pattern and the second pixel definition pattern in a plan view.

14. A method of manufacturing a display device, comprising:
forming a preliminary sacrificial layer on an insulating layer on which a first lower electrode and a second lower electrode spaced apart from the first lower electrode are disposed;
forming a light blocking layer comprising a light blocking material on the preliminary sacrificial layer;
patterning the light blocking layer such that areas of the preliminary sacrificial layer are exposed, the areas of the preliminary sacrificial layer overlapping the first and second lower electrodes in a plan view;
etching the preliminary sacrificial layer in the areas exposed through the patterned light blocking layer using the patterned light blocking layer as a mask; and
heat-treating the patterned light blocking layer.

15. The method of claim 14, wherein a pixel definition layer overlapping a side surface of the preliminary sacrificial layer in a plan view is formed from the patterned light blocking layer by the heat-treating of the light blocking layer.

16. The method of claim 14, wherein the patterning of the light blocking layer comprises:
forming a first preliminary pixel definition pattern to expose an area of the preliminary sacrificial layer overlapping the first lower electrode in a plan view; and
forming a second preliminary pixel definition pattern spaced apart from the first preliminary pixel definition pattern to expose an area of the preliminary sacrificial layer overlapping the second lower electrode in a plan view.

17. The method of claim 16, wherein the etching of the preliminary sacrificial layer comprises:
forming a first sacrificial pattern using the first preliminary pixel definition pattern as a mask; and
forming a second sacrificial pattern using the second preliminary pixel definition pattern as a mask.

18. The method of claim 17, wherein the heat-treating of the light blocking layer comprises:
forming a first pixel definition pattern overlapping a side surface of the first sacrificial pattern in a plan view; and
forming a second pixel definition pattern overlapping a side surface of the second sacrificial pattern in a plan view.

19. The method of claim 18, further comprising:
forming a cover layer overlapping a separation space between the first pixel definition pattern and the second pixel definition pattern in a plan view after the heat-treating of the light blocking layer.

20. The method of claim 14, wherein the etching of the preliminary sacrificial layer is performed by a wet etching method.
